(19) United States
(12) Patent Application Publication
(10) Pub. No.: US 2010/0182099 A1
(43) Pub. Date: Jul. 22, 2010

(54) FILTER ADAPTED TO DSL LOOP CUSTOMER SERVICE END

(76) Inventor: Hsi-Fan Chang, Guangdong (TW)

Correspondence Address: Dr. BANGER SHIA;Patent Office of Bang Shia, 102 Lindencrest Ct., Sugar Land, TX, 77479-5201, US

(21) Appl. No.: 12/091,744

(22) PCT Filed: Nov. 27, 2006
(86) PCT No.: PCT/CN06/03168

§ 371 Date: Apr. 26, 2008

(51) Int. Cl. H04M 1/00; H03H 7/00

(52) U.S. Cl. 333/175

(57) ABSTRACT

A filter adapted to DSL loop customer service end includes filter circuit, transistor control circuit, and a capacitor connected in parallel to a line, the transistor control circuit and the capacitor respectively connected to the filter circuit; the transistor control circuit is electrically connected to the capacitor; the transistor control circuit controls on and off of telecommunication signals; whereas there is no current flows through a telephone line when the telephone set is in on-hook status, the transistor control circuit is not conducted through under on-hook status so to stop the telecommunication signals from flowing through, thus to warrant that the telecommunication signals in the talking line will not shunt to a line in hook-on status for upgrading signal quality in talking mode.

### BACKGROUND OF THE INVENTION

(a) Field of the Invention

The present invention is related to a filter, and more particularly, to one adapted to DSL loop customer service end.

(b) Description of the Prior Art

DSL (Digital Subscriber Line) relates to a series of super modems at a transmission rate much higher than that of the ordinary simulation modem and even provides 300 times faster mega level transmission rate than that of the ordinary simulation modem. The most important advantage of the DSL is to realize high speed network application simply by using the existing telephone network configuration, e.g., application in telephone, facsimile, and other daily communication. DSL may be taken as a high speed data channel for people to use it in various high speed data applications. Whereas DSL technology involves the use of the ordinary telephone line (unlike other high speed transmission technology such as Cable Modem), DSL technology has been thought as the optimal selection to solve the problem of ‘the last mile’. So far DSL not only includes the well-know ADSL (Asymmetrical Digital Subscriber Line) technology but also embraces VDSL, HDSL, SDSL, and HDSL2 technologies. All these technologies have been comprehensively applied in the market and considered as matured technologies; therefore no elaboration will be given to these DSL technologies.

### SUMMARY OF THE INVENTION

The primary purpose of the present invention is to provide a filter to correct defects found with the prior art that is adapted to DSL loop customer service end to effectively reduce DSL loop signal decay after connection in parallel to guarantee the communication equipments connected in parallel to receive better telecommunication signals.

To achieve the purpose, the present invention adopts the following technical option:

A filter adapted to DSL loop customer service end includes a filter circuit conducted and connected to the DSL loop; and at least one transistor control circuit and a capacitor connected in parallel with the line with the transistor control circuit and the capacitor respectively connected to the filter circuit, and the transistor control circuit is connected to the capacitor connected in parallel with the line for the transistor control circuit to control the on and off of the telecommunication signals.

The transistor control circuit includes biased voltage circuit, transistor, and over voltage protection circuit. The biased voltage circuit and the over voltage protection circuit are respectively connected to the transistor.

The filter circuit is comprised of one or a plurality of inductance. The transistor is comprised of at least two triodes connected in reverse direction, and a diode for over voltage protection circuit is connected to where between the collector and the emitter to provide over voltage protection for the triode. A biased resistance disposed for the biased voltage circuit is connected in series to the emitter and a base of the triode to provide function of biased voltage for the triode.

A capacitor is disposed between two emitters respectively from both triodes to provide a better signal passage.

### BRIEF DESCRIPTION OF THE DRAWINGS

FIG. 1 is a schematic view showing a circuit frame structure of a first preferred embodiment of the present invention.

FIG. 2 is a schematic view showing a circuit frame structure of a transistor control circuit taken from FIG. 1.

FIG. 3 is a schematic view showing a substantial circuit structure of FIG. 1.

FIG. 4 is a schematic view showing a circuit frame structure of a second preferred embodiment of the present invention.

FIG. 5 is a schematic view showing a substantial circuit structure of FIG. 4.

### DETAILED DESCRIPTION OF THE PREFERRED EMBODIMENTS

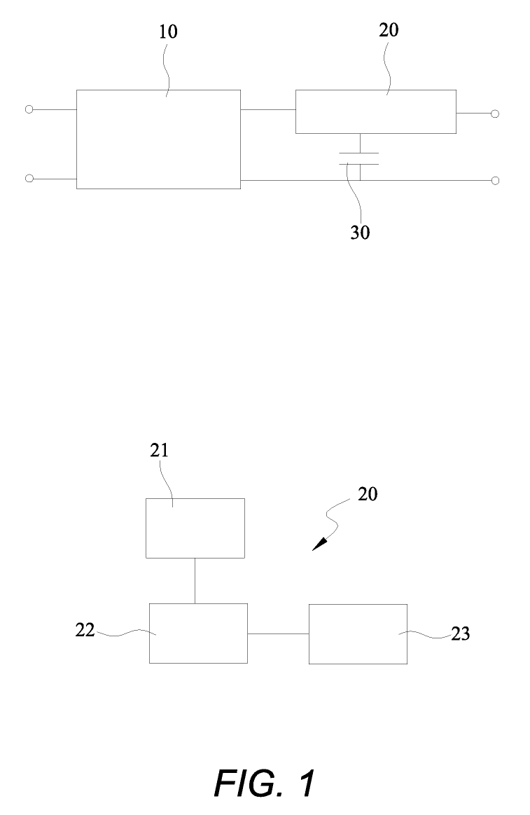

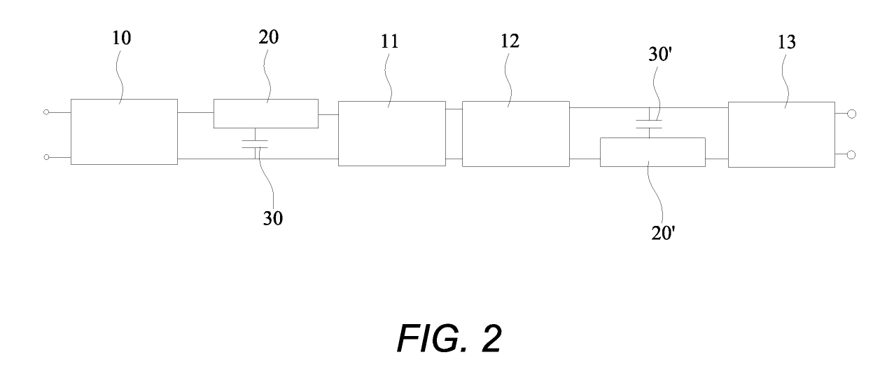

Referring to FIGS. 1 and 2 for a schematic view of a circuit frame structure of a first preferred embodiment of the present invention, a filter adapted to DSL loop customer service end includes a filter circuit 10, a transistor control circuit 20, and a capacitor 30 connected in parallel to the circuit. Wherein the transistor control circuit 20 and the capacitor 30 are respectively connected to the filter circuit 10; the transistor control circuit 20 is connected to the capacitor 30; and the transistor control circuit 20 controls on and off status of the capacitor 30.

The transistor control circuit 20 is comprised of a biased voltage circuit 21, a transistor 22, and an over voltage protection circuit 23. The biased voltage circuit 21 and the over voltage protection circuit 23 are respectively connected to the transistor 22.

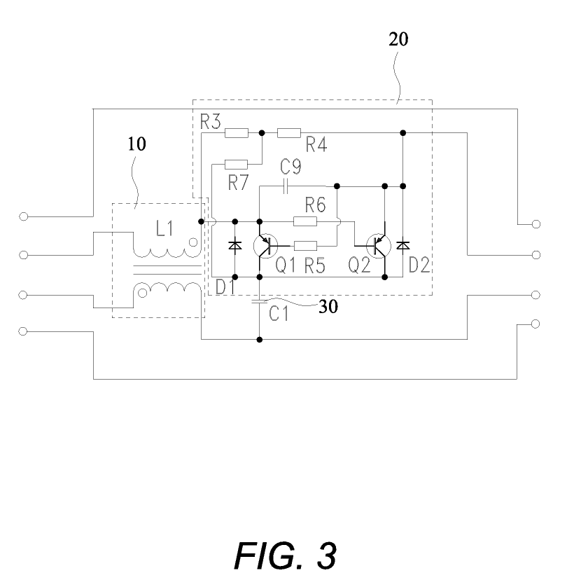

As also illustrated in FIG. 3 for a schematic view showing a substantial circuit structure of the preferred embodiment, the filter circuit is comprised of an inductance L1, a capacitor 30 is related to C1, the transistor 22 is comprised of two triodes Q1 and Q2 connected to each other in reverse direction. Two diodes D1 and D2 disposed corresponding to the over voltage protection circuit 23 are respectively connected in parallel to where between the collector and emitter of each of both triodes Q1 and Q2 so to provide over voltage protection for both triodes Q 1 and Q2. Biased resistances R3, R4, R5, and R6 respectively disposed in corresponding to the biased voltage circuit 21 connected between the emitter and a base each of both triodes Q1 and Q2 provides function of biased voltage for both triodes Q1 and Q2. A capacitor C9 is disposed between emitters of both triodes Q1 and Q2 to provide a better signals passage.

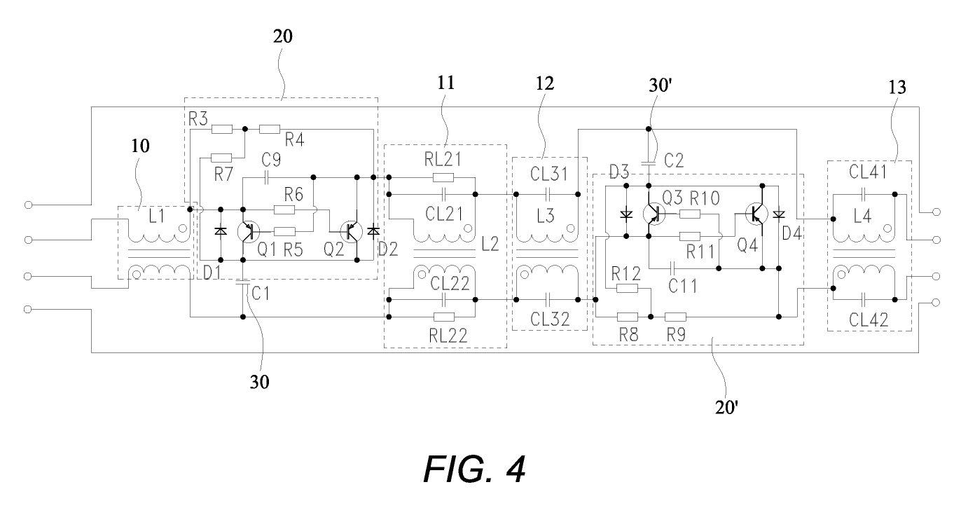

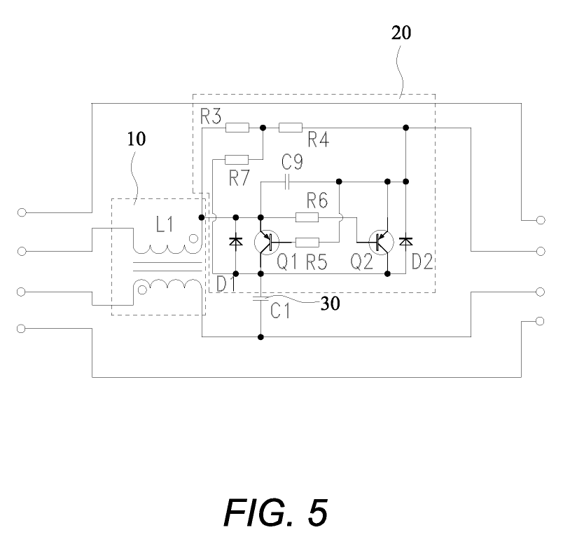

Now referring to FIGS. 4 and 5 for a schematic view showing a circuit structure of a second preferred embodiment of the present invention, as illustrated in FIG. 4, a filter adapted to the DSL loop customer service end is comprised of four filter circuits 10, 11, 12, and 13; both filter circuits 10 and 12 are respectively connected to the transistor circuits 20, 20′ and capacitors 30, 30′. Wherein, the structure each of the transistor control circuits 20, 20′ is the same as that of first preferred embodiment to contain the same biased voltage circuit, transistor, and over voltage protection circuit, therefore the structure will not be elaborated herein. The transistor control circuit 20, and the output end of the capacitor 30 are connected to another filter circuit 11. The filter circuit 11 is then connected to the filter circuit 12 for the transistor control circuit 20′, the capacitor 30′ connected to the filter circuit 12 to connect the last level of filter circuit 13; and finally, the filter circuit 13 is connected through the telephone line.

As illustrated in FIG. 5 for a schematic view showing a substantial circuit of the second preferred embodiment, the filter circuit 10 is comprised of an inductance L1, and the transistor in the transistor control circuit 20 is comprised of two triodes Q1 and Q2 connected in inverse direction, and two diodes D1, D2 disposed for over voltage protection circuit are connected in parallel to where between the collector and the emitter of each of both triodes Q1 and Q2 to provide over voltage protection for both triodes Q1 and Q2′ biased resistances R3, R4, R5, and R6 disposed for the biased voltage circuit are respectively connected to where between the emitter and the base of each of both triodes Q1 and Q2 so to provide the function of biased voltage for both triodes Q1 and Q2. A capacitor C9 is disposed between two emitters respectively from both triodes Q1 and Q2 to deliver a better signal passage. The filter circuit 11 is comprised of an inductance L2 to receive the processed signals and transfer them to an inductance L3 disposed in the next filter circuit 12, where the signals are processed by the inductance L3 and transferred to the transistor control circuit 20′ and the capacitor 30′ in the filter circuit 12. The capacitor 30′ is related to C2, and the transistor control circuit 20′ is the same as the transistor control circuit 20 connected to the filter circuit 10, wherein the transistor is also comprised of two triodes Q3 and Q4 connected in inverse direction. Diodes D3 and D4 disposed corresponding to the over voltage protection circuit are respectively connected in parallel to where between the collector and the emitter of each of both triodes Q3 and Q4 so to provide over voltage protection for both triodes Q3 and Q4. Biased resistances R8, R9, R10, and R11 disposed for the biased voltage circuit are respectively connected to where between the emitter and the base of each of both triodes Q3 and Q4 so to provide function of biased voltage for both triodes Q3 and Q4. A capacitor C11 is disposed between two emitters of both triodes Q3 and Q4 to deliver a better signal passage. Finally, the signals pass through a inductance L4 in the final level filter circuit 13 to constitute the filter of the present invention. The second preferred embodiment differs from the first preferred embodiment in that the second preferred embodiment realizes its purpose by using four-level control. The number of level of control varies depending on the filed needs, therefore is not limited. The filter circuit and the working principle between the transistor control circuit and capacitor of the second preferred embodiment is same as that of the first preferred embodiment, therefore is not elaborated herein.

The prevent invention provides an improved structure of a filter adapted to a DSL loop customer service end; and the application for a utility patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. A filter adapted to a DSL loop customer service end comprising a filter circuit and one or a plurality of transistor control circuit and a capacitor connected in parallel to a line; the transistor control circuit and the capacitor being respectively connected to the filter circuit; the transistor control circuit being connected to the capacitor; and the transistor control circuit controlling on and off the telecommunication signals.

2. The filter adapted to a DSL loop customer service end as claimed in claim 1, wherein the transistor control circuit is comprised of biased voltage circuit, transistor, and over voltage protection circuit; and the biased voltage circuit and the over voltage protection circuit are respectively connected to the transistor.

3. The filter adapted to a DSL loop customer service end as claimed in claim 2, wherein the transistor is comprised of multiple triodes connected in inverse direction, a diode disposed for over voltage protection circuit is connected in parallel to where between a collector and an emitter of the triode to protect over voltage protection for the triode; and a biased resistance disposed for the biased voltage circuit is connected in series to where between the emitter and a base of the triode to provide function of biased voltage for the triode.

4. The filter adapted to a DSL loop customer service end as claimed in claim 3, wherein a capacitor is disposed between two emitters from two triodes to deliver better signal passage.

5. The filter adapted to a DSL loop customer service end as claimed in claim 1 or 3, wherein the filter circuit is comprised of one or a plurality of inductance.
